(19) United States
(12) Patent Application Publication
(10) Pub. No.: US 2008/0093736 A1
(43) Pub. Date: Apr. 24, 2008

(54) SEMICONDUCTOR DEVICE

(75) Inventor: Satoru TOKUDA, Shiga (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/874,948

(22) Filed: Oct. 19, 2007

(30) Foreign Application Priority Data
Oct. 23, 2006 (JP) 2006-287616

(51) Int. Cl. H01L 23/48

(52) U.S. Cl. 257/735; 257/E23.01

(57) ABSTRACT

A semiconductor die has a top surface and a bottom surface. A source contact, a gate contact and a gate finger are formed on the top surface. The source contact has a slit and the gate finger is disposed in the slit of the source contact. A drain contact is formed on the bottom surface. An insulation layer is formed on the top surface to cover the gate finger. A semiconductor device includes the semiconductor die and an electrically conductive sheet attached to the source contact with a conductive paste. The electrically conductive sheet has a concave portion disposed above the gate finger. An air gap is formed between the concave portion and the insulation layer. By including the air gap, the stress that occurs between the electrically conductive sheet and the insulation layer can be reduced, thus an occurrence of a crack in the insulation layer can be prevented. In addition, since the electrically conductive sheet includes no slit formed therein, the electrical resistance of the electrically conductive sheet does not increase.

### CROSS-REFERENCE TO RELATED APPLICATIONS

This application is based upon, claims the benefit of priority of, and incorporates by reference the contents of Japanese Patent Application No. 2006-287616 filed on Oct. 23, 2006.

### BACKGROUND

1. Field of the Invention

The present invention relates to a semiconductor device, more particularly to a semiconductor device having an electrically conductive sheet that is bonded to a source contact.

2. Description of Related Art

FIG. 2A and FIG. 2B are respectively a sectional view and a plan view that show an example of a conventional semiconductor device (see U.S. Pat. No. 6,414,362 B1). The cross section taken along the line II-II in FIG. 2B corresponds to the sectional view in FIG. 2A. A semiconductor device 100 includes a semiconductor die which includes a plurality of transistor cells (not shown) formed in a semiconductor body 101. Each transistor cell includes a source region, a drain region and a gate electrode, and is connected in parallel to each other, thereby forming a power transistor. The semiconductor body 101 has a bottom surface on which a drain contact 103 is formed, and a top surface on which a comb-shaped first metallized region defining a source contact 102 is formed, a second metallized region defining a gate contact 110 and a third metallized region defining gate fingers 104. The drain contact 103 and the source contact 102 are electrically connected to the drain region and the source region, respectively. The gate contact 110 is electrically connected to the gate electrode via the gate finger 104. The semiconductor die further includes an insulation layer 105 that covers the gate fingers 104. The semiconductor device 100 further includes a conductive paste 107 formed on both the source contact 102 and the insulation layer 105, a metal sheet 106 bonded to the source contact 102 and the insulation layer 105 with the conductive paste 107, and a bottom metal plate 108 electrically connected to the drain contact 103.

As shown in FIG. 2B, the source contact 102 includes slits 109 formed therein. The comb-shaped gate fingers 104 are respectively disposed in the slits 109. The ridge portion of the comb is connected to the gate contact 110 by being disposed along the outer side of the semiconductor die. In addition, a source terminal 111, a gate terminal 112 and a drain terminal 113 are provided to the semiconductor device 100, and are electrically connected to the source contact 102, the gate contact 110 and the drain contact 103, respectively.

In the semiconductor device 100, the metal sheet 106 is bonded to the source contact 102 by covering the gate fingers 104 with the insulation layer 105, and then by forming the conductive paste 107 on the entire top surface of the semiconductor die including the source contact 102 and the insulation layer 105. Accordingly, the electrical resistance between the source contact 102 and the metal sheet 106 can be reduced. However, a temperature change occurs by turning on and off the power transistor, and thereby stress occurs due to the difference in the coefficients of thermal expansion between the insulation layer 105 and the metal sheet 106. This stress causes a crack 120 in the insulation layer 105, which leads to the problem of losing a reliability of the semiconductor device 100.

FIG. 3A and FIG. 3B are respectively a sectional view and a plan view that show a semiconductor device of a related art. The cross-section taken along the line III-III in FIG. 3B corresponds to the sectional view in FIG. 3A. In a semiconductor device 200, a plurality of slits 116a are each formed at a position of the metal sheet 116, the position being above each of the gate fingers 30, thereby forming the metal sheet 116 into a comb shape. In the semiconductor device 200, neither the conductive paste 107 nor the metal sheet 116 are formed on the insulation layer 40 covering the gate fingers 30.

As a consequence, such a crack as occurred in the case of the semiconductor device 100 does not occur in the insulation layer 105 in the semiconductor device 200. On the other hand, the electrical resistance of the metal sheet 116 increases as the slits 116a become wider. For this reason, the slits 116a need to be formed as narrow as possible, and thus, fine metal working is required to form the metal sheet 116. Hence, the cost of manufacturing may be increased.

The comb-shaped metal sheet 116 with slits 116a has another problem. Specifically, it is difficult to maintain the flatness among the end portions of the tines of the comb of the metal sheet 116. Accordingly, part of the metal sheet 116 may not adhered to the source contact 20. Furthermore, the metal sheet 116 has a portion, such as the vicinity of the gate contact 80 (the portion encircled by a dotted line L1), the width of which is narrower. This may cause the electrical resistance to increase in some cases.

### SUMMARY

The present invention seeks to solve or to improve one or more of the above problems at least in part suppressing an increase in the electrical resistance of an electrically conductive sheet and preventing an occurrence of a crack in an insulation layer.

In one embodiment of the present invention, a semiconductor die has a top surface and a bottom surface. A first metallized region, a second metallized region and a third metallized region are formed on the top surface. The first metallized region has a slit and the third metallized region is disposed in the slit of the first metallized region. An insulation layer is formed on the top surface to cover the third metallized region. A semiconductor device includes the semiconductor die and an electrically conductive sheet attached to the first metallized region. The electrically conductive sheet has a concave portion (extended portion) disposed above the third metallized region. An air gap is formed between the concave portion (extended portion) of the electrically conductive sheet and the insulation layer.

With the air gap formed between the concave portion (extended portion) of the electrically conductive sheet and the insulation layer, an occurrence of a crack in the insulation layer can be prevented. This is because stress that occurs between the electrically conductive sheet and the insulation layer can be small due to the air gap, even when there is a difference in the coefficients of thermal expansion therebetween. In addition, though a slit is formed by cutting the electrically conductive sheet, no part of the electrically conductive sheet needs to be cut in forming the concave portion (extended portion). Accordingly, the electrical resistance of the electrically conductive sheet does not increase. Hence, a semiconductor device with low electrical resistance and excellent reliability can be formed.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A and FIG. 1B are respectively a sectional view and a plan view that show a semiconductor device according to an embodiment of the present invention;

FIG. 2A and FIG. 2B are respectively a sectional view and a plan view that show a conventional semiconductor device; and

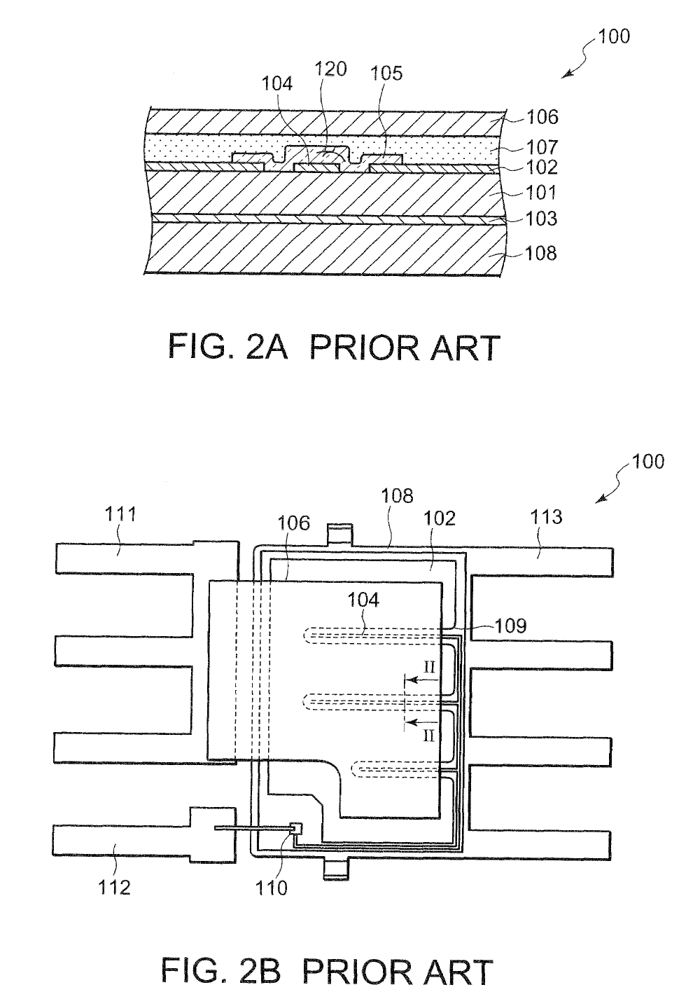

FIG. 3A and FIG. 3B are respectively a sectional view and a plan view that show a semiconductor device of a related art.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

In the description of the drawings, the same reference numerals and symbols will be used to designate the same components, so that the description will be omitted.

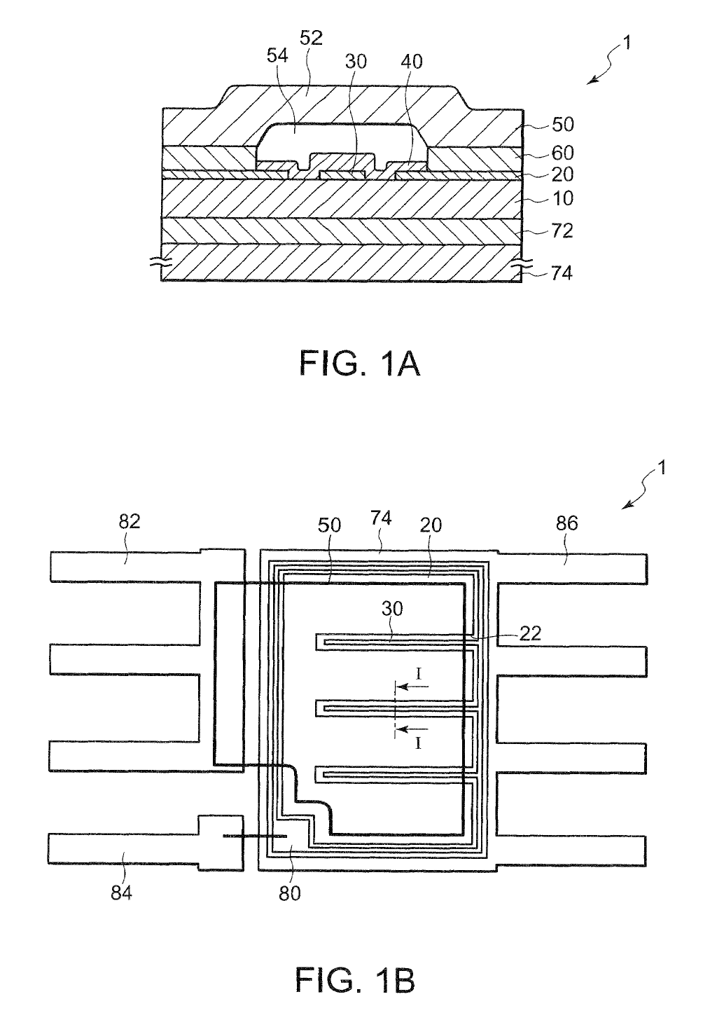

FIG. 1A and FIG. 1B are respectively a sectional view and a plan view that show a semiconductor device according to an embodiment of the present invention. The cross section taken along the line I-I in FIG. 1B corresponds to FIG. 1A. A semiconductor die includes a semiconductor body 10, a source contact 20 (first metallized region), gate fingers 30 (third metallized regions), a gate contact 80 (second metallized region) and an insulation layer 40. The semiconductor body 10 includes, for example, a power metal-oxide semiconductor field-effect transistor (MOSFET) (not shown) formed therein. The source contact 20 is electrically connected to a source region of the power MOSFET, while the gate fingers 30 are electrically connected to a gate electrode of the power MOSFET. In addition, the gate contact 80 is electrically connected to the gate finger 30. The insulation layer 40 covers the gate fingers 30. The number of the gate fingers 30, that is, parts that correspond to the tines of a comb, may be single or plural. The ridge portion of the comb is connected to the gate contact 80 by being disposed along the outer side of the semiconductor die. The gate fingers 30 and the gate contact 80 may have a single metallized structure formed of a single metallized layer so as to respectively form one part and another part of the single metallized structure. A semiconductor device 1 includes the semiconductor die and an electrically conductive sheet 50, which is provided so as to cover the source contact 20 and the insulation layer 40, and which is electrically connected to the source contact 20. The electrically conductive sheet 50 is typically a metal sheet, but is not limited thereto. The electrically conductive sheet 50 is attached to the source contact 20 with a conductive paste 60, for example, a silver paste.

The electrically conductive sheet 50 serves to electrically connect the source contact 20 and a source terminal 82, which is an external terminal. A concave portion 52 (extended portion) is formed in a portion on the face of the semiconductor body 10 side of the electrically conductive sheet 50, the portion being above the gate finger 30. FIG. 1A shows an example in which concave portion 52 is formed on the electrically conductive sheet 50 by stamping, so that the portion of the electrically conductive sheet 50 in which the concave portion 52 is formed has an arch shape. The concave portion 52 is, however, not limited to the above-mentioned one, but includes a case in which only the face of the semiconductor body 10 side of the electrically conductive sheet 50 is carved while the face of the other side of the electrically conductive sheet 50 is kept flat. An air gap 54 is provided between the insulation layer 40 and the concave portion 52 of the electrically conductive sheet 50. Although the conductive paste 60 is provided between the source contact 20 and the electrically conductive sheet 50, it is preferable to avoid providing the conductive paste 60 on the insulation layer 40. This is because the conductive paste 60 may fill the air gap 54 when being formed on the insulation layer 40.

The semiconductor die further includes a drain contact 72 (fourth metallized region) formed on the bottom surface of the semiconductor body 10 and electrically connected to a drain region (not shown) of the power MOSFET. The drain contact 72 and a metal plate 74 are connected to each other using a conductive paste (not shown), for example, a silver paste or the like.

As shown in FIG. 1B, a plurality of slits 22 are formed in the source contact 20, and the gate fingers 30 are respectively disposed in the slits 22. Although the source contact 20 shown in FIG. 1B has a comb shape, the source contact 20 is formed into a U-shape in the case where the gate fingers 30 included in the semiconductor die is single. In addition, the semiconductor device 1 includes the source terminal 82 (first external terminal), a gate terminal 84 (second external terminal) and a drain terminal 86 (third external terminal), which are electrically connected to the source contact 20, the gate contact 80 and the drain contact 72, respectively.

The semiconductor device 1 includes the concave portion 52 formed on the electrically conductive sheet 50, and the air gap 54 is provided between the insulation layer 40 covering the gate fingers 30 and the concave portion 52. Due to the air gap 54, the stress that occurs between the electrically conductive sheet 50 and the insulation layer 40 can be made small even when there is a difference in the coefficients of thermal expansion therebetween. Hence, an occurrence of a crack in the insulation layer 40 can be prevented. Moreover, though a slit is formed by cutting the electrically conductive sheet 50, no part of the electrically conductive sheet 50 needs to be cut in forming the concave portion 52. Accordingly, the electrical resistance of the electrically conductive sheet 50 does not increase. Hence, it is possible to form a semiconductor device with low electrical resistance and excellent reliability. In addition, the concave portion 52 can be easily formed by means of stamping or the like, which makes it possible to minimize the increase of the manufacturing cost.

It is also possible to prevent an occurrence of a crack in the insulation layer 40 more certainly by forming the air gap 54 above the entire insulation layer 40. For this reason, the concave portion 52 is preferably formed in accordance with the shape of the insulation layer 40.

The electrically conductive sheet 50 may be equal in size to the source contact 20. This makes it possible to ensure the area for the section at which the electrically conductive sheet 50 and the source contact 20 are connected, thereby to form a power MOSFET with low electrical resistance. In addition, by employing the electrically conductive sheet 50 including the concave portion 52 formed thereon, the electrical resistance of the electrically conductive sheet 50 can be suppressed compared to the case of employing the electrically conductive sheet 50 including slits formed therein. Thus, the number of the gate fingers 30 can be increased. Consequently, the distance between the gate finger 30 and the gate electrode in each transistor cell can be made small, resulting in reducing the gate resistance, and thereby high-speed operation of the semiconductor device 1 can be achieved.

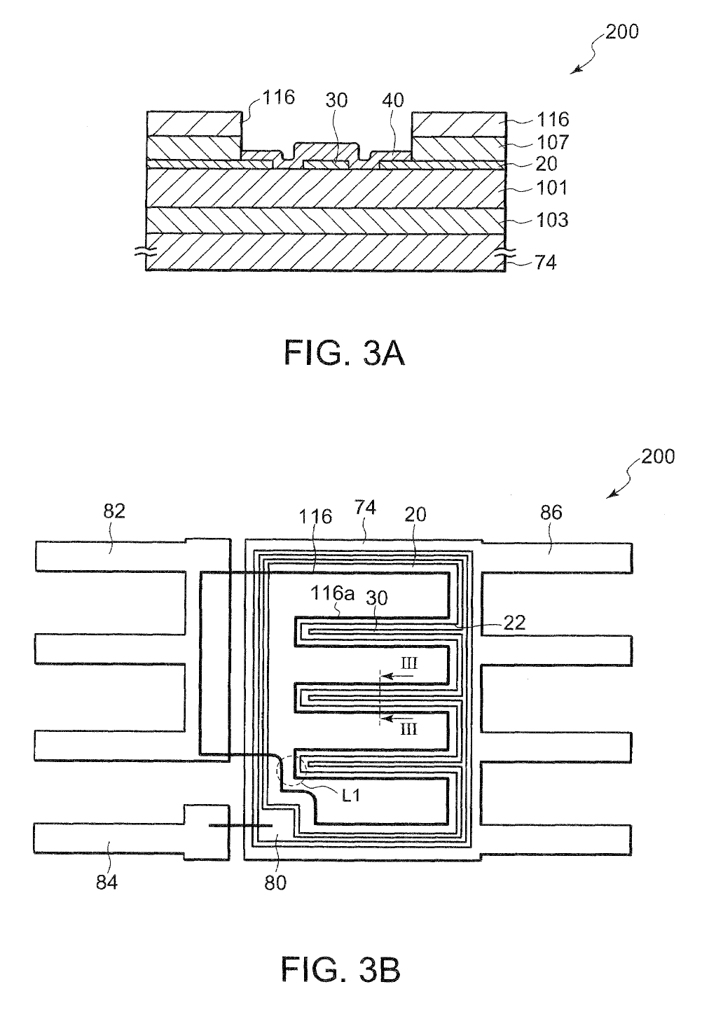

Furthermore, by employing the electrically conductive sheet 50 including concave portion 52 formed thereon, no slit is formed in the electrically conductive sheet 50. Thus, it is easy to keep the electrically conductive sheet 50 flat, and the electrically conductive sheet 50 is adhered to the source securely compared to the semiconductor device 200. In addition, in contrast to the case of the narrow portion enclosed by a dotted line L1 in FIG. 3B, current path of the electrically conductive sheet 50 becomes larger.

Although the invention has been described above in connection with several preferred embodiments thereof, it will be appreciated by those skilled in the art that those embodiments are provided solely for illustrating the invention, and should not be relied upon to construe the appended claims in a limiting sense. For example, the source contact 20 and the drain contact 72 in the example described above are respectively formed on the top surface and the bottom surface of the semiconductor body 10. However, the drain contact 72 may be formed on the top surface. In such a case, the metal plate 74 may be eliminated. In addition, the drain terminal 86 and the drain contact 72 may be connected by use of, for example, another electrically conductive sheet or the like.

In addition, the transistor to be employed is not limited to a MOSFET, but may be an insulated gate bipolar transistor (IGBT), a bipolar transistor or the like. In a bipolar transistor, for example, it may replace the terms, “source,” “gate,” and “drain” by “emitter,” “base,” and “collector,” respectively.

What is claimed is:

1. A semiconductor device, comprising:
a semiconductor die having a top surface and a bottom surface, said top surface including a first metallized region having a slit, a second metallized region, a third metallized region disposed in said slit of said first metallized region and electrically connected to said second metallized region, and an insulation layer covering said third metallized region;
an electrically conductive sheet attached to said first metallized region and having a concave portion disposed above said third metallized region;
an air gap formed between said concave portion of said electrically conductive sheet and said insulation layer;
a first external terminal electrically connected to said electrically conductive sheet; and
a second external terminal electrically connected to said second metallized region.

2. The semiconductor device of claim 1, wherein said second metallized region and said third metallized region are formed of a single metallized structure.

3. The semiconductor device of claim 1, wherein said concave portion of said electrically conductive sheet is free from being attached to by a conductive paste.

4. The semiconductor device of claim 1, wherein said first metallized region includes another slit thereby forming a comb shape, said third metallized region further comprises another third metallized region, thereby forming a comb shape, and each of said third metallized region is disposed in each of said slit of said first metallized region.

5. The semiconductor device of claim 1, wherein said semiconductor die includes a power MOSFET.

6. The semiconductor device of claim 1, wherein said electrically conductive sheet is a metal sheet.

7. The semiconductor device of claim 1, wherein said concave portion of said electrically conductive sheet is formed an arch shape.

8. The semiconductor device of claim 1, further comprises a third external terminal, wherein said semiconductor die further comprises a fourth metallized region electrically connected to said third external terminal.

9. A semiconductor device of claim 8, wherein said fourth metallized region is formed on said bottom surface of said semiconductor die.

10. A semiconductor device, comprising:
a semiconductor die having a top surface and a bottom surface, said top surface including a first metallized region having a slit, a second metallized region, a third metallized region disposed in said slit of said first metallized region and electrically connected to said second metallized region, and an insulation layer covering said third metallized region;
an electrically conductive sheet attached to said first metallized region and having an extended portion over said third metallized region with an air gap between said extended portion and said insulation layer;
a first external terminal electrically connected to said electrically conductive sheet; and
a second external terminal electrically connected to said second metallized region.

11. A semiconductor device of claim 10, wherein said extended portion of said electrically conductive sheet is concave to form said air gap.

12. The semiconductor device of claim 10, wherein said second metallized region and said third metallized region are formed of a single metallized structure.

13. The semiconductor device of claim 10, wherein said extended portion of said electrically conductive sheet is free from being attached to by a conductive paste.

14. The semiconductor device of claim 10, wherein said first metallized region includes another slit thereby forming a comb shape, said third metallized region further comprises another third metallized region, thereby forming a comb shape, and each of said third metallized region is disposed in each of said slit of said first metallized region.

15. The semiconductor device of claim 10, wherein said semiconductor die includes a power MOSFET.

16. The semiconductor device of claim 10, wherein said electrically conductive sheet is a metal sheet.

17. The semiconductor device of claim 10, wherein said extended portion of said electrically conductive sheet is formed an arch shape.

18. The semiconductor device of claim 10, further comprises a third external terminal, wherein said semiconductor die further comprises a fourth metallized region electrically connected to said third external terminal.

19. A semiconductor device of claim 18, wherein said fourth metallized region is formed on said bottom surface of said semiconductor die.
